(19) United States
(12) Patent Application Publication
(10) Pub. No.: US 2025/0140580 A1
(43) Pub. Date: May 1, 2025

(54) WET PROCESSING APPARATUS

(71) Applicant: NATIONAL INSTITUTE OF ADVANCED INDUSTRIAL SCIENCE AND TECHNOLOGY, Tokyo (JP)

(72) Inventors: Shiro HARA, Tsukuba-shi (JP); Kazumasa NEMOTO, Tsukuba-shi (JP); Sommawan KHUMPUANG, Tsukuba-shi (JP); Yuuki ISHIDA, Tokyo (JP)

(73) Assignee: NATIONAL INSTITUTE OF ADVANCED INDUSTRIAL SCIENCE AND TECHNOLOGY, Tokyo (JP)

(21) Appl. No.: 18/835,762

(22) PCT Filed: Dec. 27, 2022
(86) PCT No.: PCT/JP2022/048360

§ 371 Date: Aug. 5, 2024

(30) Foreign Application Priority Data
Feb. 24, 2022 (JP) 2022-026920

(51) Int. Cl. H01L 21/67; H01L 21/687

(52) U.S. Cl. CPC H01L 21/67051; H01L 21/68721

(57) ABSTRACT

A wet processing apparatus capable of carrying out a wet process efficiently for both the surfaces of a workpiece is provided. The wet processing apparatus comprises: a stage (19); a plurality of support pins (20a, 20b) protruding upward from the stage (19), respectively, and supporting an outer edge of a workpiece (W) at positions spaced from each other in a circumferential direction; a rotation driving unit for rotating the stage (19) about a rotation axis extending in a vertical direction; a supply nozzle (22) for supplying a process liquid to the workpiece (W) supported by the plurality of support pins (20a, 20b) from above the workpiece (W); and a holding ring (29) placed on the stage (19) so as to surround the plurality of support pins (20a, 20b) below the workpiece (W).

### TECHNICAL FIELD

The present invention relates to a wet processing apparatus in the semiconductor processes.

### BACKGROUND ART

Recently, as a production line for semiconductor devices, a minimal fab system for various kinds and very small quantity production has been proposed. In the minimal fab system, for responding to its purpose described above, based on the production of a single device on a wafer having the size of 0.5 inch (half inch size), a plurality of movable unit process apparatuses is provided in the steps of such production, and the rearrangement of the plurality of unit process apparatuses in a flow-shop or a job-shop is facilitated.

As a wet processing apparatus to be employed in the minimal fab system, in particular, as a cleaning machine, Patent Literature 1 discloses a spin cleaning machine that drops a cleaning liquid onto a wafer while rotating a stage on which a wafer is placed. According to the spin cleaning machine as disclosed in Patent Literature 1, the cleaning liquid stays on the upper surface (top surface) of the wafer due to the surface tension, the wafer can be efficiently cleaned with less cleaning liquid.

### CITATION LIST

### Patent Literature

Patent Literature 1: JP-A-2015-106688

### SUMMARY OF INVENTION

### Technical Problem

However, in the spin cleaning machine according to Patent Literature 1, the cleaning liquid cannot stay on the back surface (lower surface) side of the wafer placed on the stage for a long duration of time. This causes a problem that the back surface of the wafer cannot be appropriately cleaned.

The present invention has been made in view of the circumstances of the prior art described above, and an object thereof is to provide a wet processing apparatus capable of carrying out a wet process efficiently for both the surfaces of a workpiece.

### Solution to Problem

In order to achieve the object described above, the present invention provides a wet processing apparatus comprising: a stage; a plurality of support pins protruding upward from the stage, respectively, and supporting an outer edge of a workpiece at positions spaced from each other in a circumferential direction; a rotation driving unit for rotating the stage about a rotation axis extending in a vertical direction; and a supply nozzle for supplying a process liquid to the workpiece supported by the plurality of support pins from above the workpiece, wherein the wet processing apparatus comprises a holding ring placed on the stage so as to surround the plurality of support pins below the workpiece.

### Advantageous Effects of Invention

According to the present invention, it is possible to obtain a wet processing apparatus capable of carrying out a wet process efficiently for both the surfaces of a workpiece.

### BRIEF DESCRIPTION OF DRAWINGS

FIG. 1 schematically illustrates a spin cleaning machine according to the present embodiment.

FIG. 2 is a schematic side view of the inside of a process chamber.

FIG. 3 is a schematic top view of the inside of a process chamber.

FIG. 4 illustrates a holding ring.

FIG. 5 is a control block diagram of a spin cleaning machine.

FIG. 6 illustrates a state of a cleaning liquid that has been supplied to a wafer.

FIG. 7 illustrates a relation between the volume of a cleaning liquid supplied per one time from a supply nozzle and the holding time of the cleaning liquid on both the surfaces of a wafer.

FIG. 8 illustrates a relation between the rotational speed of a spin table and the holding time of a cleaning liquid on both the surfaces of a wafer.

FIG. 9 schematically illustrates the side and top of the inside of a process chamber according to a modification.

### DESCRIPTION OF EMBODIMENTS

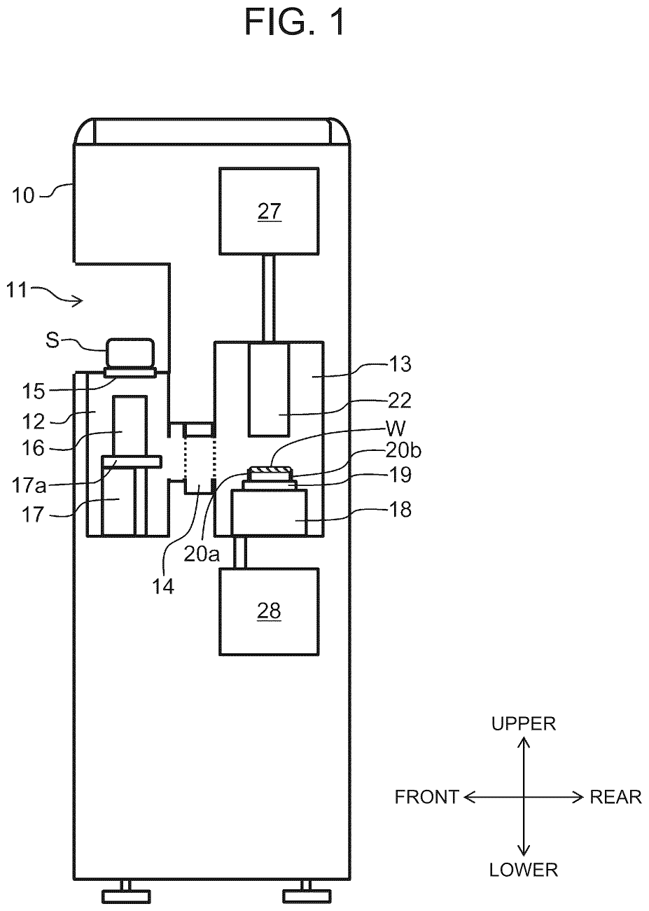

Hereinafter, an embodiment of the present invention will be described with reference to the drawings. FIG. 1 schematically illustrates a spin cleaning machine 1 according to the present embodiment. The spin cleaning machine 1 (wet processing apparatus) is a machine for cleaning (for example, by resist stripping, etching, removing adhering residue, and the like) the upper surface and back surface of a wafer W (object to be processed). Furthermore, the spin cleaning machine 1 is a machine that cleans the wafer W while rotating it. Still further, the spin cleaning machine 1 is a heating and wet processing apparatus which supplies a cleaning liquid (process liquid) while heating the wafer W.

The spin cleaning machine 1 is a minimal cleaning machine based on the concept of minimal fab (fabrication), which is housed within a housing 10 having a predetermined size. Here, the minimal fab concept is suitable for a high-mix and low-volume semiconductor production market, and can respond to various types of resource saving, energy saving, investment saving, and/or high-performance fabrication. According to the minimal fab concept, a minimal production system for reducing the scale of production which is, for example, disclosed in JP-A-2012-54414 can be realized.

The wafer W has a disk-shaped appearance having a predetermined size, for example, 12.5 mm (half-inch size) in diameter. However, the shape and size of the wafer W are not limited to the examples described above. The wafer W has a predetermined pattern formed in advance and is in a state before being cleaned. The wafer W may be, for example, a bare silicon wafer from which a photoresist film has been removed.

The spin cleaning machine 1 includes the housing 10 having a substantially rectangular parallelepiped shape whose longitudinal direction corresponds to the vertical direction. The housing 10 is designed to block the entry of the fine particles and gas molecules into the inside of the housing 10. In an upper portion of the foreside surface of the housing 10, a recess 11 which is recessed rearward and extends therethrough in the left and right direction is formed. Inside the housing 10, a front chamber 12 and a process chamber 13 are formed.

The front chamber 12 is a space formed immediately below the recess 11. The process chamber 13 is a space formed on the rear side of the front chamber 12. Furthermore, an opening/closing door 14 is provided between the front chamber 12 and the process chamber 13. The opening/closing door 14 is movable between an open position allowing the front chamber 12 and the process chamber 13 to communicate with each other and a close position allowing the space between the front chamber 12 and the process chamber 13 to be blocked. Bringing the opening/closing door 14 in the open position causes the wafer W to move between the front chamber 12 and the process chamber 13. On the other hand, bringing the opening/closing door 14 to the close position prevents the entry of fine particles and gas molecules into the process chamber 13.

The front chamber 12 is designed as a PLAD (Particle Lock Air-tight Docking) system that allows the wafer W housed in a minimal shuttle S to be taken in and out of the housing 10 without letting it be exposed to the outside air. More specifically, a docking port 15 is formed between the recess 11 and the front chamber 12 (ceiling surface of the front chamber 12). The docking port 15 is a port for loading and unloading the wafer W into and from the spin cleaning machine 1. The minimal shuttle S in which the wafer W is housed is placed on the docking port 15. The minimal shuttle S is formed with a lid body and a bottom body, which can be brought into contact with each other and separated from each other in the vertical direction. Bringing the lid body and the bottom body to be joined with each other with the wafer W being housed in the minimal shuttle S can prevent the entry of fine particles and gas molecules into the inside of the minimal shuttle S.

The front chamber 12 includes an elevating apparatus 16. The elevating apparatus 16 raises and lowers the wafer W within the front chamber 12. More specifically, the elevating apparatus 16 separates the bottom body supporting the wafer W from the lid body and lowers it, or raises the bottom body supporting the wafer W and causes it to join with the lid body.

Furthermore, the front chamber 12 includes a conveying apparatus 17. The conveying apparatus 17 conveys the wafer W between the elevating apparatus 16 and a stage 19 which will be described later. The conveying apparatus 17 includes a conveying arm 17a that slides (extends and contracts) in the front and rear direction between the front chamber 12 and the process chamber 13. More specifically, the conveying arm 17a receives the wafer W from the bottom body supported by the elevating apparatus 16 that has been lowered, enters the process chamber 13 from the front chamber 12, and places the wafer W on support pins 20a to 20d of the stage 19. Furthermore, the conveying arm 17a receives the wafer W from the support pins 20a to 20d, leaves the process chamber 13 and enters the front chamber 12, and transfers the wafer W to the bottom body supported by the elevating apparatus 16.

The process chamber 13 is a space for cleaning the wafer W conveyed by the conveying apparatus 17. In the process chamber 13, a flow (downflow) of nitrogen gas from the upper side to the lower side is formed. Furthermore, bringing the opening/closing door 14 in the close position causes the process chamber 13 to be maintained at a positive pressure with respect to the front chamber 12. This prevents the entry of fine particles and gas molecules into the process chamber 13 during cleaning of the wafer W.

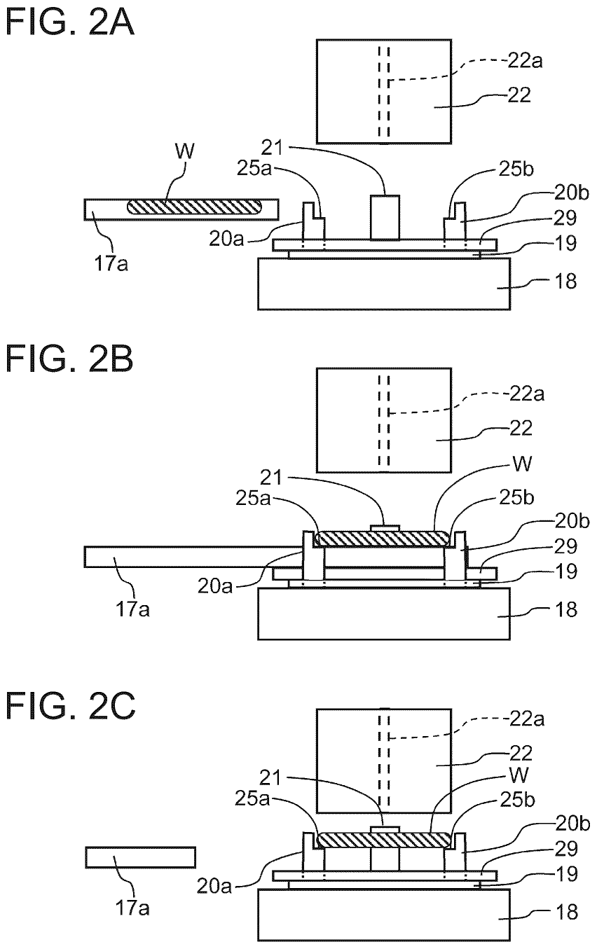

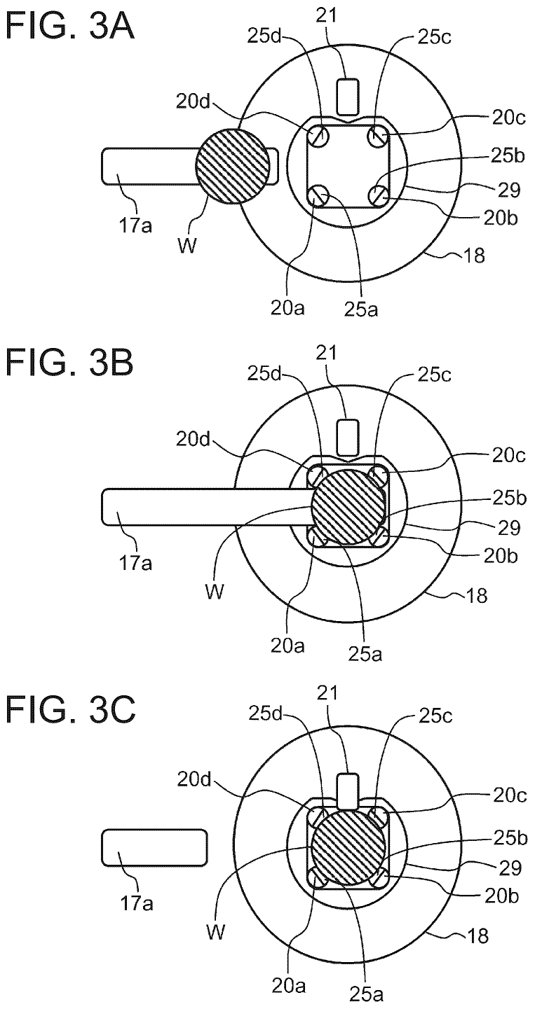

FIG. 2 is a schematic side view of the inside of the process chamber 13. FIG. 3 is a schematic top view of the inside of the process chamber 13. As illustrated in FIG. 1 to FIG. 3, in the process chamber 13, a spin table 18, the stage 19, the plurality of support pins 20a, 20b, 20c, 20d, a chuck 21, and a supply nozzle 22 are arranged.

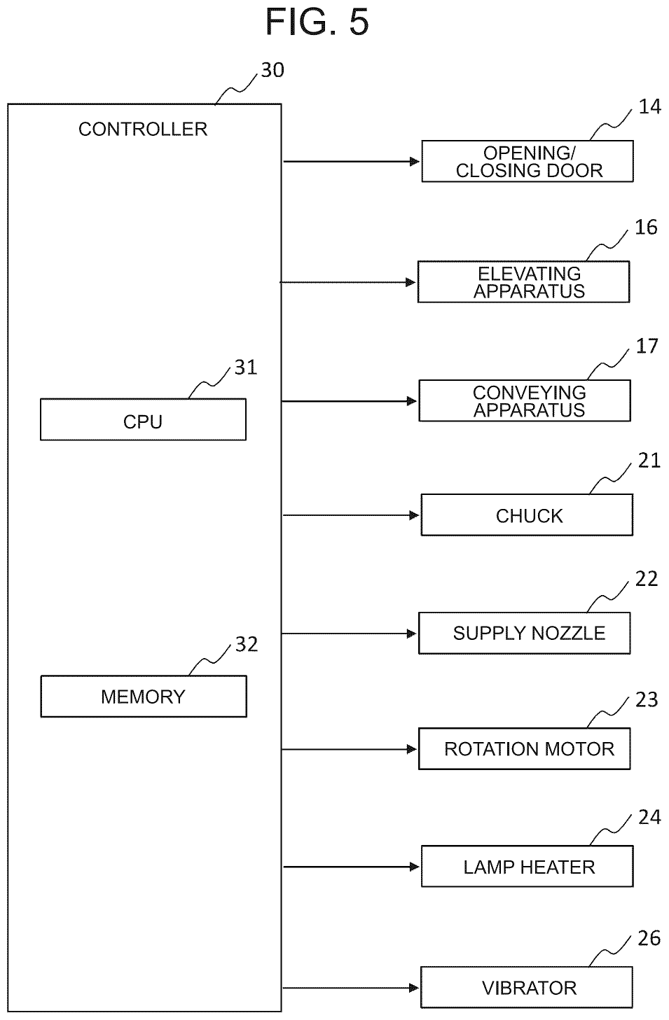

The spin table 18 is supported within the process chamber 13 so as to be rotatable about a rotation axis extending in the vertical direction. The stage 19 is provided at the center of the top surface of the spin table 18. The stage 19 is a circular portion protruding upward from the top surface of the spin table 18. The driving force of a rotation motor 23 (rotation driving unit) illustrated in FIG. 5 transmitted to the spin table 18 causes the spin table 18 to rotate together with the stage 19 and the support pins 20a to 20d.

Furthermore, the spin table 18 has a built-in lamp heater 24 (heating unit) illustrated in FIG. 5. The lamp heater 24 heats the wafer W (more specifically, an interface between the wafer W and a cleaning liquid) supported by the support pins 20a to 20d. As the lamp heater 24, for example, a xenon lamp or the like can be employed.

The support pins 20a to 20d protrude upward from the top surface of the stage 19. Furthermore, the support pins 20a to 20d are arranged with a predetermined distance in the circumferential direction (in the present embodiment, at a 90-degree interval). Still further, the support pins 20a to 20d are provided with stepped portions 25a, 25b, 25c, 25d, respectively, each of which is formed by cutting out the inside of its edge (top end). Placing the outer edge of the wafer W on the stepped portions 25a to 25d causes the wafer W to be supported by the support pins 20a to 20d. However, the number of support pins 20a to 20d is not limited to four, but may be three or five or more.

The chuck 21 is arranged between the adjacent support pins 20c, 20d on the spin table 18. The chuck 21 is designed to be in contact with and separated from the wafer W supported by the support pins 20a to 20d. Bringing the chuck 21 into contact with the wafer W causes the wafer W to be fixed on the support pins 20a to 20d. On the other hand, separating the chuck 21 from the wafer W causes the wafer W that has been fixed to be released, which allows the wafer W to be taken out from the support pins 20a to 20d.

The supply nozzle 22 is designed to be movable in the vertical direction above the stage 19. The end surface (bottom surface) of the supply nozzle 22 has a circular shape which is slightly larger than the wafer W in diameter. The supply nozzle 22 includes a supply passage 22a that is open toward the lower surface of the supply nozzle 22. The supply nozzle 22 supplies the wafer W supported by the support pins 20a to 20d with a cleaning liquid (for example, chemical liquid, ultrapure water), which is an example of a process liquid, nitrogen gas, and the like, through the supply passage 22a. Furthermore, the supply nozzle 22 includes a built-in vibrator 26 (see FIG. 5) for vibrating the supply nozzle 22 at a high frequency (for example, 1 MHZ).

As a chemical liquid, for example, hydrofluoric acid, ozone water, a mixed solution of sulfuric acid and hydrogen peroxide solution, and an aqueous potassium hydroxide solution can be used. The supply nozzle 22 may supply the chemical liquid, ultrapure water, and nitrogen gas through the single supply passage 22a, and alternatively, may have a plurality of supply passages for supplying the chemical liquid, ultrapure water, and nitrogen gas, respectively.

The housing 10 further houses a cleaning liquid tank 27 for storing the cleaning liquid to be used for cleaning the wafer W, a waste liquid tank 28 for storing the cleaning liquid discharged from the process chamber 13 after being used for cleaning the wafer W (hereinafter, referred to as a “waste liquid”), a removal adsorption tower (not illustrated) for removing the exhausted harmful gas, a drive system (not illustrated) such as a motor and an air cylinder for driving each section, a controller 30 for controlling the operations of the spin cleaning machine 1 (see FIG. 5), and the like.

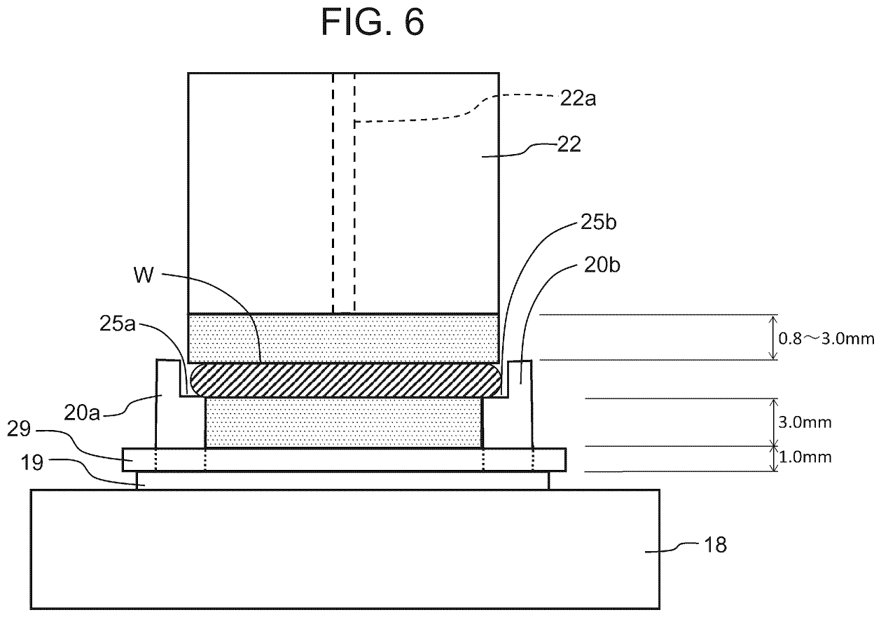

Furthermore, as illustrated in FIG. 2 and FIG. 3, a detachable holding ring 29 is attached to the stage 19. The holding ring 29 is placed on the stage 19 so as to surround the supporting pins 20a to 20d. This causes the lower surface of the holding ring 29 to come into contact with the top surface of the stage 19. On the other hand, between the back surface of the wafer W placed on the stepped portions 25a to 25d and the top surface of the holding ring 29, a gap in the vertical direction which allows the conveying arm 17a to enter is formed. For example, as illustrated in FIG. 6, the thickness dimension of the holding ring 29 is 1 mm, and the gap in the vertical direction formed between the wafer W and the holding ring 29 is set to be 3 mm. However, the specific dimensions thereof are not limited to the examples illustrated in FIG. 6.

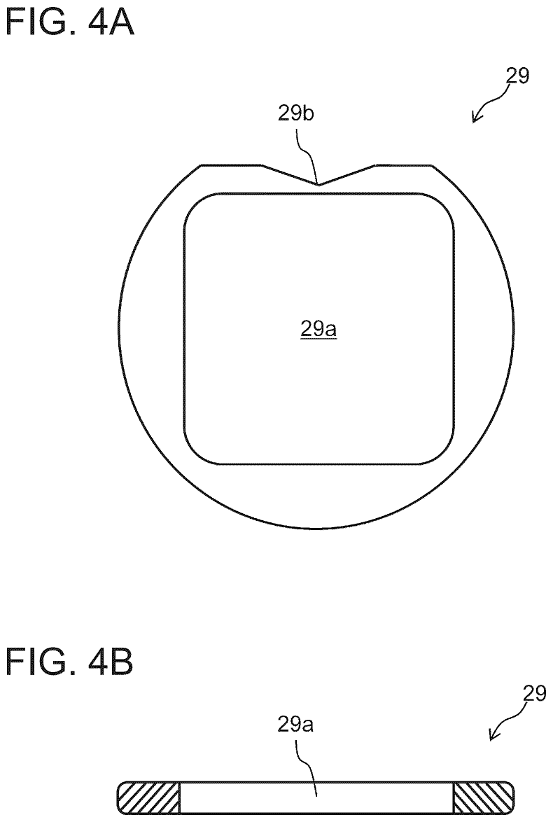

FIG. 4 illustrates the holding ring 29. As illustrated in FIG. 4, the holding ring 29 has a substantially ring-shaped appearance. The holding ring 29 is made of a material containing, for example, vinylidene fluoride rubber (FKM), synthetic quartz, or polytetrafluoroethylene (PTFE). However, the material of the holding ring 29 is not limited to the examples described above.

The holding ring 29 includes an opening 29a extending through the center portion in the thickness direction. The inner peripheral surface of the holding ring 29 (in other words, the shape of the opening 29a) is a quadrangle with its corners chamfered. Each of the sides between the chamfered corners extends straightly (in other words, forming a flat surface). As illustrated in FIG. 3, the holding ring 29 is placed on the stage 19 such that the chamfered corners are contact with the support pins 20a to 20d. The opening 29a is formed in the holding ring 29 so as to have the shape corresponding to the number of support pins 20a to 20d. That is, if the number of support pins is five, the holding ring is provided with a pentagonal opening with its corners chamfered.

The outer peripheral surface of the holding ring 29 is circular. However, as illustrated in FIG. 4 (A), the holding ring 29 includes a cut-out portion 29b provided to avoid interfering with the chuck 21 at a position facing the chuck 21 (in other words, a portion of the holding ring 29 in the circumferential direction) when being placed on the stage 19. As illustrated in FIG. 2, the external dimension of the largest part of the holding ring 29 (in other words, the external dimension excluding the position of the cut-out portion 29b) is larger than the diameter of the stage 19.

Furthermore, as illustrated in FIG. 4 (A), the thickness of the holding ring 29 in the radial direction differs at each position in the circumferential direction. More specifically, the holding ring 29 is designed such that the thickness in the radial direction increases as the distance from the positions with which the support pins 20a to 20d are in contact (in other words, the positions of the chamfered corners) increases, except for the position at which the cut-out portion 29b is formed. In other words, in the circumferential direction of the holding ring 29, the contact area with the stage 19 increases as the distance from the support pins 20a to 20d increases.

FIG. 5 is a control block diagram of the spin cleaning machine 1. As illustrated in FIG. 5, the spin cleaning machine 1 includes a controller 30 having a CPU 31 (Central Processing Unit) and a memory 32. The memory 32 may be configured with, for example, a ROM (Read Only Memory), a RAM (Random Access Memory), an HDD (Hard Disk Drive), or a combination thereof. The CPU 31 reads the program code stored in the memory 32 and executes it, whereby the controller 30 implements the processing to be described later.

However, the specific configuration of the controller 30 is not limited thereto, and may be implemented by hardware such as an ASIC (Application Specific Integrated Circuit), an FPGA (Field-Programmable Gate Array), or the like.

The controller 30 controls the overall operations of the spin cleaning machine 1. More specifically, the controller 30 opens and closes the opening/closing door 14, causes the elevating apparatus 16 to raise and lower the wafer W, causes the conveying apparatus 17 to convey the wafer W, causes the chuck 21 to advance and retract, raises and lowers the supply nozzle 22, causes the supply nozzle 22 to supply the cleaning liquid and nitrogen gas, causes the rotary motor 23 to rotate the spin table 18, causes the lamp heater 24 to heat the wafer W, and causes the vibrator 26 to vibrate the supply nozzle 22.

Next, with reference to FIG. 2, FIG. 3, and FIG. 6, the processes in which the spin cleaning machine 1 cleans the wafer W will be described. FIG. 6 illustrates the state of the cleaning liquid that has been supplied to the wafer W. It is assumed that the holding ring 29 is attached to the stage 19 prior to the cleaning of the wafer W.

Firstly, as illustrated in FIG. 2 (A) and FIG. 3 (A), the controller 30 moves the conveying arm 17a that has received the wafer W from the elevating apparatus 16 toward the support pins 20a to 20b. At this time, the opening/closing door 14 is positioned in the open position, the spin table 18 is stopped, the chuck 21 is retracted, and the supply nozzle 22 is raised.

Next, as illustrated in FIG. 2 (B) and FIG. 3 (B), the controller 30 lowers the conveying arm 17a at the position where the wafer W faces the stepped portions 25a to 25d. This causes the outer edge of the wafer W to be placed on the stepped portions 25a to 25d and to be separated from the conveying arm 17a. As described above, the gap in the vertical direction between the back surface of the wafer W and the top surface of the holding ring 29 is set to such an extent that the conveying arm 17a that has been lowered and the holding ring 29 do not interfere with each other (for example, 3 mm).

Next, as illustrated in FIG. 2 (C) and FIG. 3 (C), the controller 30 causes the conveying arm 17a to leave the process chamber 13, moves the opening/closing door 14 to the close position, brings the chuck 21 into contact with the outer edge of the wafer W, lowers the supply nozzle 22, rotates the spin table 18, and heats the wafer W using the lamp heater 24. Furthermore, the controller 30 causes a downflow of the nitrogen gas to generate in the process chamber 13, and makes the pressure in the process chamber 13 positive. Still further, the controller 30 supplies the cleaning liquid to the wafer W from the supply nozzle 22 that has been vibrated by the vibrator 26.

As illustrated in FIG. 6, the distance between the upper surface of the wafer W and the lower surface of the supply nozzle 22 is set to, for example, 0.8 mm to 3.0 mm. Then, the controller 30 supplies the chemical liquid from the supply nozzle 22 to the wafer W while rotating the spin table 18 at a low speed (for example, 50 rpm or lower). The controller 30 supplies, for example, 0.6 ml to 0.8 ml of the chemical liquid per one time from the supply nozzle 22 over one second at intervals of once every ten seconds.

As illustrated with a dot hatching in FIG. 6, this causes the chemical liquid to be held between the upper surface (top surface) of the wafer W and the lower surface of the supply nozzle 22 by the surface tension. The space between the back surface (lower surface) of the wafer W and the top surface of the stage 19 is filled with the chemical liquid blocked by the holding ring 29. This causes both the surfaces of the wafer w to be simultaneously cleaned.

Then, the controller 30 rotates the spin table 18 a low speed so that the chemical liquid on both the sides of the wafer W slowly leaks out in the radial direction while being agitated. More specifically, the chemical liquid held between the back surface of the wafer W and the holding ring 29 is slowly discharged through the space between the top surface of the stage 19 and the lower surface of the holding ring 29.

The controller 30 continues this state for about 20 seconds to 45 seconds, for example. Next, the controller 30 rotates the spin table 18 at a high speed (for example, 1000 rpm or more) to blow out the chemical liquid on both the upper and lower surfaces of the wafer W by the centrifugal force. Next, the controller 30 carries out the processes described above using ultrapure water instead of the chemical liquid. This causes the chemical liquid remaining on both the surfaces of the wafer W to be washed away.

Then, the controller 30 blows the nitrogen gas from the supply nozzle 22 to the wafer W while rotating the spin table 18 at a high speed. This causes the wafer W to be dried. Furthermore, the controller 30 takes out the wafer W supported by the support pins 20a to 20d to the outside of the spin cleaning machine 1 using the conveying apparatus 17 and the elevating apparatus 16.

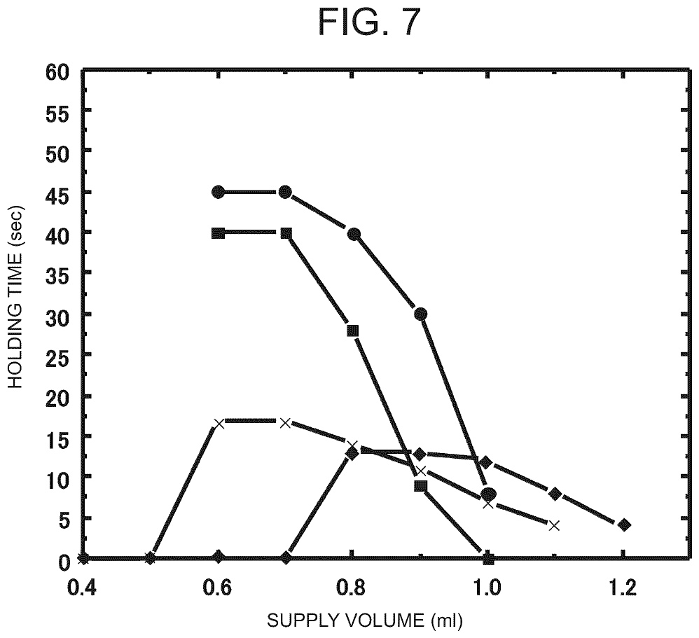

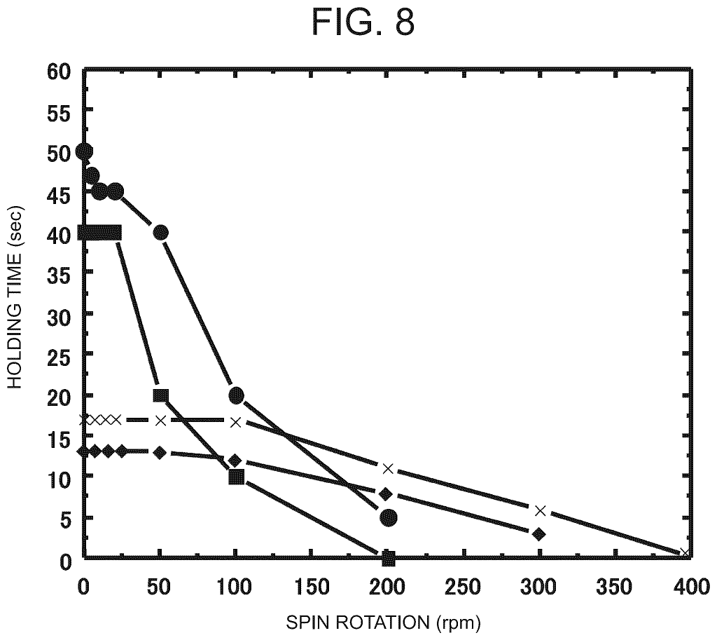

Next, the relation between the supply volume of the cleaning liquid, the rotational speed of the spin table 18, and the holding time of the cleaning liquid will be described with reference to FIG. 7 and FIG. 8. FIG. 7 illustrates a relation between the volume of the cleaning liquid supplied per one time from the supply nozzle 22 and the holding time of the cleaning liquid on both the surfaces of the wafer W. FIG. 8 illustrates the relation between the rotational speed of the spin table 18 and the holding time of the cleaning liquid on both the surfaces of the wafer W. Note that the holding time was measured by the visual observation of the time during which the cleaning liquid has been held on both the surfaces of the wafer W.

In FIG. 7 and FIG. 8, the plots “●” represent the results of an experiment using a combination of the hydrophilic wafer W and the holding ring 29 formed of PTFE. The plots “▪” represent the results of an experiment using a combination of the hydrophobic wafer W and the holding ring 29 formed of PTFE. The plots “x” represent the results of an experiment using a combination of the hydrophilic wafer W and the holding ring 29 formed of FKM. The plots “♦” represent the results of an experiment using a combination of the hydrophobic wafer W and the holding ring 29 formed of FKM.

As shown in FIG. 7, when the volume of the cleaning liquid supplied per one time from the supply nozzle 22 is set to 0.6 ml to 0.8 ml, the cleaning liquid is held on both the surfaces of the wafer W for 13 seconds or more. In particular, in the holding ring 29 formed of PTFE, the cleaning liquid is held for 28 seconds or more, and the holding period becomes longer as the supply volume decreases. Note that, in the experiment illustrated in FIG. 7, the rotational speed of the spin table 18 is set to 10 rpm.

If the supply volume of the cleaning liquid is too small, the space between the upper surface of the wafer W and the lower surface of the supply nozzle 22 and the space surrounded by the back surface of the wafer W and the holding ring 29 cannot be simultaneously filled with the cleaning liquid. On the other hand, if the supply volume of the cleaning liquid is too large, the cleaning liquid overcomes the limit of the surface tension and sharply overflows. That is, in the half-inch-size wafer W, a predetermined volume allowing the cleaning liquid to be held on the upper surface of the wafer W by the surface tension and allowing the space surrounded by the back surface of the wafer W and the holding ring 29 to be filled with the cleaning liquid is 0.6 ml to 0.8 ml. However, the appropriate value of the supply volume of the cleaning liquid varies depending on the material and diameter of the wafer W, the physical properties of the cleaning liquid, the material of the holding ring 29, and the like.

Furthermore, as shown in FIG. 8, when the rotational speed of the spin table 18 is set to be equal to or less than 50 rpm, the cleaning liquid is held on both the surfaces of the wafer W for 13 seconds or more. In particular, in the holding ring 29 formed of PTFE, the cleaning liquid is held for 20 seconds or more, and the holding time becomes longer as the rotational speed is slower. In the experiment illustrated in FIG. 8, the supply volume of the cleaning liquid for the hydrophilic wafer W is set to 0.7 ml, and the supply volume of the cleaning liquid for the hydrophobic wafer W is set to 0.9 ml.

The rotational speed of the spin table 18 that is too high causes the cleaning liquid to be immediately discharged by the centrifugal force. That is, the predetermined rotational speed allowing the cleaning liquid to remain in the space between the upper surface of the wafer W and the lower surface of the supply nozzle 22 and the space surrounded by the back surface of the wafer W and the holding ring 29 is equal to or less than 50 rpm. On the other hand, the cleaning liquid is not uniformly supplied to the entire wafer W with the spin table 18 being stopped, and accordingly, the cleaning liquid is preferably supplied with the spin table 18 being rotated at a low speed.

According to the embodiment described above, placing the holding ring 29 on the stage 19 so as to surround the support pins 20a to 20d enables the cleaning liquid to be held not only on the upper surface side of the wafer W but also on the back surface side thereof. As a result, both the surfaces of the wafer W can be cleaned simultaneously.

Note that, alternatively, both the surfaces of the wafer W may be cleaned by immersing the wafer W in a storage container in which a cleaning liquid is stored. However, in this case, it is necessary to prepare a large space for installing the storage container and a large volume of the cleaning liquid. Further alternatively, both the surfaces of the wafer W may be cleaned by reversing the wafer W after cleaning the upper surface of the wafer W to clean the back surface thereof. However, in this case, it is necessary to prepare a mechanism for reversing the wafer W, and also it takes time to clean both the surfaces of the wafer W.

That is, according to the embodiment described above, the spin cleaning machine 1 for cleaning both the surfaces of the wafer W with a simple structure can be realized while saving the volume of a cleaning liquid. Furthermore, simultaneous cleaning of both the surfaces of the wafer W can improve the throughput of the spin cleaning machine 1.

Furthermore, according to the embodiment described above, forming the holding ring 29 to have the shape as illustrated in FIG. 4 (A) enables increase in the contact area between the stage 19 and the holding ring 29 as the distances from the positions with which the support pins 20a to 20d are contact increase. This allows for reduction in the speed at which the cleaning liquid leaks out of the gap between the stage 19 and the holding ring 29.

Furthermore, according to the embodiment described above, setting the volume of the cleaning liquid supplied per one time from the supply nozzle 22 and the rotational speed of the spin table 18 to appropriate values, respectively, enables increase in the time during which the cleaning liquid remains on both the surface sides of the wafer W. This allows for appropriate cleaning of the wafer W with the small number of times, and thus saving of the volume of the cleaning liquid and improvement in the throughput of the spin cleaning machine 1 can be realized.

Furthermore, according to the embodiment described above, heating the interface between the wafer W and the cleaning liquid using the lamp heater 24 enables the temperature of the cleaning liquid to be kept in a temperature zone having a high cleaning effect. Still further, vibrating the cleaning liquid using the vibrator 26 enables the cleaning liquid to be uniformly spread over the entire area of the wafer W, and thus the cleaning liquid to be uniformly heated. Still further, the holding ring 29 formed of PTFE bends due to the increase in the temperature, which reduces the gap between the holding ring and the stage 19 and thus further increases the holding time of the cleaning liquid.

### Modification

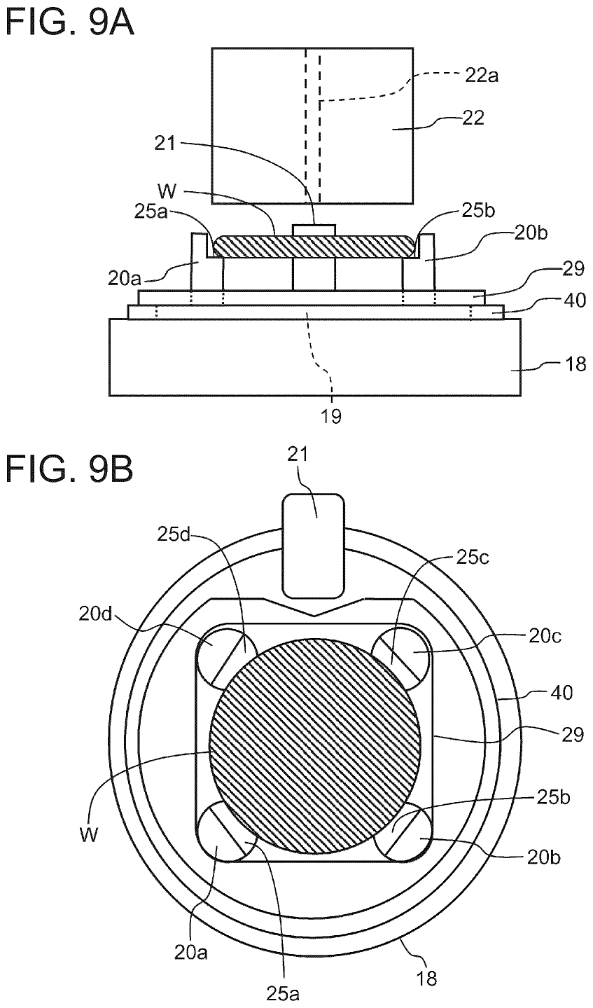

With reference to FIG. 9, a modification of the embodiment described above will be explained. FIG. 9 schematically illustrates the side and top of the inside of the process chamber 13 according to the modification. The components common to those in the embodiments described above are provided with the same reference signs and the detailed description therefor will be omitted, and the differences therefrom will be mainly described. The modification illustrated in FIG. 9 differs from the embodiment described above in that an O-ring 40 is further provided while the other features are the same as those in the embodiment described above.

The O-ring 40 is arranged along the outer peripheral surface of the stage 19 so as to surround the stage 19. The thickness dimension of the O-ring 40 is set to be equal to or slightly more than the protruding height of the stage 19. The external dimension of the O-ring 40 is set to be more than that of the holding ring 29.

That is, the O-ring 40 is in contact with the lower surface of the holding ring 29 over the entire circumference of the holding ring 29. This can prevent the cleaning liquid from leaking from between the upper surface of the stage 19 and the lower surface of the holding ring 29, resulting in further extension of the holding time of the cleaning liquid on the back surface side of the wafer W.

The present invention is not limited to the spin cleaning machine for cleaning the wafer W, but also can be applied to any wet processing apparatus for carrying out a wet process of a workpiece using a process liquid in the semiconductor processes. In such a case, for examples, a wet processing apparatus may be an etching machine, a developing machine, or the like, and a process liquid may be an etchant, a developer, or the like.

The embodiment of the present invention has been described so far. The present invention is not limited to the embodiment described above, and various modifications can be made for the present invention. For example, the embodiment described above has been described in detail for the purpose of making the present invention easily understood, and is not necessarily limited to the one having all the features described above. Furthermore, some of the features according to the present embodiment can be replaced with other features according to a different embodiment, and other features can be added to the structure of the present embodiment. Still further, some of the features according to the present embodiment can include other features of a different embodiment, be deleted, and/or replaced.

### REFERENCE SIGNS LIST

1 . . . spin cleaning machine (wet processing apparatus)
10 . . . housing
11 . . . recess
12 . . . front chamber
13 . . . process chamber
14 . . . opening/closing door
15 . . . docking port
16 . . . elevating apparatus
17 . . . conveying apparatus
17a . . . conveying arm
18 . . . spin table
19 . . . stage
20a, 20b, 20c, 20d . . . support pin
21 . . . chuck
22 . . . supply nozzle
22a . . . supply passage
23 . . . rotation motor
24 . . . lamp heater
25a, 25b, 25c, 25d . . . stepped portion
26 . . . vibrator
27 . . . cleaning liquid tank
28 . . . waste liquid tank
29 . . . holding ring
29a . . . opening
29b . . . cut-out portion
30 . . . controller
31 . . . CPU
32 . . . memory
40 . . . O-ring

1. A wet processing apparatus comprising:
a stage;
a plurality of support pins protruding upward from the stage, respectively, and supporting an outer edge of a workpiece at positions spaced from each other in a circumferential direction;
a rotation driving unit for rotating the stage about a rotation axis extending in a vertical direction; and
a supply nozzle for supplying a process liquid to the workpiece supported by the plurality of support pins from above the workpiece, wherein
the wet processing apparatus comprises a holding ring placed on the stage so as to surround the plurality of support pins below the workpiece.

2. The wet processing apparatus according to claim 1, wherein a thickness of the holding ring in a radial direction thereof increases as distances from positions with which the plurality of support pins is contact, respectively, increase.

3. The wet processing apparatus according to claim 1, wherein the holding ring includes a vinylidene fluoride rubber, synthetic quartz, or polytetrafluoroethylene.

4. The wet processing apparatus according to claim 1, wherein an O-ring is arranged on a position with which a lower surface of the holding ring is in contact, and an external dimension of the O-ring is more than that of the holding ring.

5. The wet processing apparatus according to claim 1, wherein the supply nozzle supplies the process liquid of a predetermined volume that held on an upper surface of the workpiece by surface tension and allowing a space surrounded by a back surface of the workpiece and the holding ring to be filled.

6. The wet processing apparatus according to claim 1, wherein the rotation driving unit rotates the stage at a predetermined rotational frequency allowing the process liquid to remain in a space between the workpiece and the supply nozzle and a space surrounded by a back surface of the workpiece and the holding ring.

7. The wet processing apparatus according to claim 1, further comprising a heating unit for heating the workpiece supported by the plurality of support pins.
